(19) United States
(12) Patent Application Publication
(10) Pub. No.: US 2026/0170202 A1
(43) Pub. Date: Jun. 18, 2026

(54) NEURAL OPTIMIZATION PLATFORM FOR MOLECULAR DISCOVERY

(71) Applicant: SHUBHAM CHANDRA, Katy, TX (US)

(72) Inventor: SHUBHAM CHANDRA, Katy, TX (US)

(21) Appl. No.: 18/981,525

(22) Filed: Dec. 14, 2024

(51) Int. Cl. G06F 30/27

(52) U.S. Cl. CPC G06F 30/27

(57) ABSTRACT

The invention, “Neural Optimization Platform for Molecular Discovery,” integrates advanced machine learning techniques and traditional computational chemistry methods to accelerate the discovery and optimization of molecules with tailored properties. It utilizes a hybrid approach by applying Graph Neural Networks (GNNs) to graph representations of fragmented molecules, allowing for the prediction of key molecular properties such as bioactivity, solubility, and reactivity. The platform combines these predictions with traditional optimization techniques, such as BRICS fragmentation and molecular docking simulations, to identify promising molecular candidates. It enhances the efficiency, accuracy, and scalability of molecular discovery in fields like pharmaceuticals, materials science, and biotechnology.

### BACKGROUND

### Technical Field

The present invention introduces an innovative hybrid approach that seamlessly integrates the capabilities of neural networks with traditional mathematical programming techniques to address complex multi-objective optimization challenges. This approach harnesses the power of Graph Neural Networks (GNNs) to model intricate, non-linear relationships within molecular data, generating potential solutions that are further refined using conventional optimization methods. This refinement ensures that the generated solutions adhere to predefined mathematical models and constraints, resulting in more accurate and practical outcomes.

The system is designed to facilitate molecular discovery by leveraging molecular fragmentation techniques to break down complex molecules into smaller, manageable components. These fragments are then analyzed using molecular docking simulations to predict interactions with biological targets. The GNNs enhance this process by efficiently predicting molecular properties based on graph-based representations of molecular structures, capturing the relationships between atoms and bonds to provide a deeper understanding of molecular behavior.

Developed independently without the aid of federal or government-sponsored research or funding, this system presents a pioneering solution for accelerating and optimizing the process of molecular discovery. By combining the predictive power of machine learning models, the accuracy of traditional optimization, and the versatility of advanced fragmentation and docking techniques, this approach significantly improves the efficiency and effectiveness of molecular discovery and optimization.

### Technical Background of the Invention

Molecular discovery is advancing rapidly through the integration of traditional experimental methods with cutting-edge computational techniques. Recent developments in this field can be categorized into several key areas that collectively enhance the speed and precision of discovering new molecules.

High-Throughput Experimentation (HTE) stands out as a pivotal method in this transformation. By combining automated synthesis with rapid screening, HTE enables the simultaneous creation and evaluation of a broad spectrum of molecular formulations. This technique significantly accelerates the discovery process by allowing the exploration of vast chemical spaces and the efficient identification of promising candidates. However, HTE remains resource-intensive and can be hampered by the complexity of data interpretation, which may limit its applicability in some cases.

Parallel to this, computational chemistry and molecular modeling have revolutionized molecular discovery. Techniques such as Molecular Dynamics (MD), Density Functional Theory (DFT), and Monte Carlo simulations offer the ability to predict molecular properties before actual synthesis. These methods reduce the need for extensive experimental trials, saving time and resources. However, they require substantial computational power, and their accuracy is often dependent on the assumptions and approximations inherent in the models.

Machine learning and AI-driven approaches have further propelled the field, using supervised learning and generative models to predict molecular properties and generate new molecular structures based on existing datasets. These technologies streamline the discovery process by reducing reliance on exhaustive experimentation, but they depend heavily on large, high-quality datasets. Additionally, challenges remain in terms of model interpretability, as AI-based predictions are often difficult to fully explain or validate.

By merging these experimental and computational techniques, molecular discovery is entering a new era characterized by greater precision, efficiency, and the potential for groundbreaking innovations. This integrated approach allows researchers to navigate complex molecular spaces more effectively, accelerating the discovery of novel compounds with tailored properties.

In molecular discovery, combinatorial chemistry is a fundamental approach for systematically generating a diverse range of molecular structures by varying monomers, functional groups, and additives. This technique, often combined with High-Throughput Experimentation (HTE), enables rapid testing and identification of promising molecular candidates. While combinatorial chemistry accelerates the discovery process, large-scale synthesis can still be time-consuming and costly. Additionally, post-synthesis characterization techniques such as rheological and mechanical analysis are critical for evaluating molecular properties, such as strength, viscosity, and reactivity, providing vital data for optimizing molecular performance. However, these methods are labor-intensive and require substantial resources for large-scale application.

Advanced quantum chemistry techniques are increasingly being used in molecular discovery to explore electronic structures and molecular reactivity. Methods such as Density Functional Theory (DFT) and ab initio calculations offer insights into molecular behavior and properties, aiding in the design of molecules with specific attributes like conductivity, magnetism, or solubility. While these techniques offer valuable predictive capabilities, they are computationally expensive and subject to limitations in terms of approximation accuracy and resource demands.

With sustainability in mind, the focus has also shifted towards the discovery of plant-based and biodegradable molecules. Through methods like bioprospecting, genetic engineering, and enzyme-catalyzed polymerization, researchers are developing environmentally friendly molecular alternatives that reduce reliance on synthetic compounds. Although these methods hold significant promise for sustainable molecular development, scaling up production remains a significant challenge.

Finally, molecular informatics plays a critical role in the accelerated discovery of new molecules by integrating data science, machine learning, and advanced algorithms. By analyzing vast datasets and applying predictive models, this approach enables the identification of new molecular candidates with desirable properties. The success of this technique depends heavily on the availability of comprehensive datasets and the interdisciplinary expertise needed to interpret complex data effectively.

These integrated methods offer a multifaceted approach to molecular discovery, balancing the need for rapid, scalable techniques with the precision of advanced computational modeling, ensuring that new molecular candidates can meet the challenges of modern applications.

In the realm of molecular discovery, ChEMBL plays a critical role by providing a comprehensive, curated database of bioactivity data on drug-like small molecules. Managed by the European Bioinformatics Institute (EBI), ChEMBL is widely used in cheminformatics and bioinformatics to offer detailed insights into molecular properties, biological targets, bioactivity assays, drug metabolism, and toxicity. The database serves as a valuable resource for modeling molecular interactions, optimizing molecular structures, and predicting drug efficacy. Researchers leverage ChEMBL's data alongside computational modeling, including machine learning and AI-driven discovery, to explore chemical space and identify novel molecules or polymers with tailored properties. This synergy between computational techniques and ChEMBL enables faster, more precise predictions in molecular and polymer discovery, accelerating both experimental and computational advancements.

A cornerstone of these computational techniques is the use of molecular fingerprints-compact digital representations of chemical structures. These fingerprints capture the presence or absence of specific molecular features, which allows algorithms to efficiently compare and analyze molecules. Represented in binary format, molecular fingerprints encode structural information, where each bit typically signifies the presence (1) or absence (0) of a particular molecular feature, such as functional groups or atom arrangements.

The integration of ChEMBL data with molecular fingerprinting is especially powerful in cheminformatics and drug discovery. By using ChEMBL's wealth of chemical and bioactivity data, researchers can generate molecular fingerprints for computational analysis. These fingerprints are central to a range of applications, including drug discovery, virtual screening, and similarity searches, where the goal is to predict molecular properties, activities, or interactions based on structural data.

Molecular fingerprints are essential tools in cheminformatics, enabling the representation of chemical structures for tasks such as virtual screening and similarity searching. Two primary types of molecular fingerprints are substructure fingerprints and atom-pair fingerprints, each suited to different molecular complexities.

Substructure Fingerprints are particularly effective for small molecules, such as drugs. They encode specific molecular substructures, including functional groups, rings, or atomic arrangements, facilitating the detection of key features associated with biological activity. In pharmaceutical research, these fingerprints help identify molecules with important pharmacophores or functional groups essential for drug development.

Atom-Pair Fingerprints are optimized for larger, more complex molecules, such as peptides or proteins. These fingerprints capture the spatial distances and relationships between atom pairs, providing detailed structural information about how different parts of a molecule relate in three-dimensional space. They are particularly useful for analyzing large molecules with intricate spatial arrangements, where the relationships between distant atoms are crucial to their function.

By employing these fingerprinting methods, researchers can effectively analyze and compare molecular structures, facilitating the identification of compounds with desired biological activities.

By combining ChEMBL's rich dataset with the precision of molecular fingerprinting, researchers can use advanced computational tools to predict and design molecules and polymers with desired properties. This integrated approach enhances the efficiency and accuracy of molecular discovery, offering significant advancements in both the experimental and computational landscapes.

In the field of molecular discovery, optimization challenges are prevalent, especially when dealing with complex molecular properties and constraints. These challenges often involve balancing conflicting molecular attributes such as stability, reactivity, and solubility, while also meeting specific performance, environmental, or regulatory standards. Traditionally, mathematical programming methods like Linear Programming (LP), Mixed-Integer Programming (MIP), and Non-Linear Programming (NLP) have been employed to address such optimization problems. However, these traditional methods face limitations when navigating highly non-linear relationships between molecular properties, large solution spaces, and the diverse nature of molecular structures.

With the advent of machine learning, particularly neural networks such as Convolutional Neural Networks (CNNs) and Recurrent Neural Networks (RNNs), molecular discovery has undergone significant transformation. These neural networks are highly effective at learning complex, non-linear patterns from extensive datasets, enabling researchers to model and predict molecular behaviors that are challenging to capture through traditional optimization techniques. Neural networks can analyze historical data on molecular structures and their associated properties, identifying correlations between molecular design and performance characteristics, such as conductivity or bioactivity.

In addition, Graph Neural Networks (GNNs) are emerging as a powerful tool for molecular discovery. GNNs are designed to handle graph-structured data, making them particularly well-suited for representing and analyzing molecules, where atoms and bonds can be treated as nodes and edges of a graph. By leveraging GNNs, researchers can gain deeper insights into how molecular structures influence properties, facilitating the design of molecules with targeted functionalities, such as improved stability or enhanced reactivity.

However, despite their power, neural networks do not always guarantee optimal or feasible solutions, especially when physical or chemical constraints are involved. This is where traditional optimization techniques complement machine learning models. For example, Linear Programming (LP) can still play a critical role in refining solutions generated by neural networks. LP is particularly useful in optimizing production processes or managing linear relationships, such as minimizing raw material costs or energy consumption while ensuring the desired molecular properties are met. Algorithms like Simplex or Interior-Point Methods offer efficient ways to handle these linear optimization problems.

Incorporating both advanced machine learning techniques like CNNs, RNNs, and GNNs, along with traditional optimization methods, provides a robust approach to molecular discovery. By combining the predictive power of neural networks with the efficiency of classical optimization, researchers can generate more accurate, feasible, and optimized molecular designs, driving advancements in various fields of molecular and polymer science.

In more complex decision-making scenarios within molecular discovery, Mixed-Integer Programming (MIP) becomes essential when discrete decisions are required, such as determining the optimal number of molecular formulations or experimental conditions. MIP is designed to handle these integer constraints and is frequently applied in scenarios like resource allocation, experimental design, or process optimization. However, the presence of integer variables in MIP problems can make them computationally intensive, particularly when the solution space grows significantly.

For many molecular discovery problems that involve intricate non-linear relationships between molecular structures and their properties, such as chemical reactivity, stability, or bioactivity, Non-Linear Programming (NLP) techniques are necessary. NLP is particularly effective at modeling these complex, non-linear effects but can be more challenging due to the possibility of multiple local optima. Techniques like Gradient Descent or Sequential Quadratic Programming (SQP) are commonly used to navigate the complex, multi-dimensional landscapes of molecular properties. While these methods are powerful, they may not always guarantee a global optimum, requiring careful consideration when optimizing molecular designs or predicting new compound behaviors.

By integrating these advanced optimization methods into molecular discovery workflows, researchers can address complex decision-making challenges and refine molecular designs with more precise and effective solutions.

Physical Programming offers a unique multi-objective optimization approach, particularly useful in molecular discovery where conflicting objectives-such as optimizing chemical reactivity while minimizing toxicity-must be balanced. Unlike traditional methods that assign fixed weights to each objective, physical programming allows researchers to define ranges of desirability for each molecular property (e.g., highly desirable stability, acceptable solubility, undesirable reactivity). This preference-based method is especially valuable in molecular design, where trade-offs between performance, environmental impact, and cost are often difficult to quantify. By converting qualitative preferences into quantitative expressions, physical programming helps guide the optimization process to identify molecules that meet a variety of performance and safety criteria.

In summary, combining the predictive power of machine learning models like neural networks with optimization techniques such as Linear Programming (LP), Mixed-Integer Programming (MIP), Non-Linear Programming (NLP), and Physical Programming provides a robust approach to molecular discovery. Machine learning models, including Convolutional Neural Networks (CNNs), Recurrent Neural Networks (RNNs), and Long Short-Term Memory networks (LSTMs), offer the ability to explore vast molecular spaces and predict complex, non-linear relationships between molecular structure and properties. Meanwhile, traditional optimization techniques ensure that solutions are feasible, optimal, and aligned with the constraints inherent in molecular design, including performance, safety, and environmental considerations.

By integrating these approaches, the molecular discovery process becomes more efficient, enabling the creation of molecules with highly tailored properties for specific applications. This hybrid strategy is accelerating the pace of innovation, enabling the development of novel molecules that meet complex, multi-faceted requirements.

Fragmentation processes are widely used in drug discovery, computational chemistry, and cheminformatics to decompose complex molecules into simpler, smaller fragments. These fragments can then be used for further analysis, virtual screening, or as building blocks for generating new molecules. In molecular discovery, fragmentation aids in exploring a broader chemical space by breaking down molecules into manageable units, allowing researchers to recombine fragments in different ways to optimize desired properties. By fragmenting molecules, researchers can systematically explore potential molecular structures while considering key factors such as reactivity, stability, solubility, and toxicity.

Different fragmentation methods are employed based on the objectives of the research, the properties of the molecules being studied, and the desired outcomes. Traditional methods, such as BRICS fragmentation, focus on breaking bonds that are considered rigid or stable, generating fragments that are chemically stable and suitable for further recombination. Alternatively, reactive fragmentation targets chemically reactive sites, while combinatorial fragmentation generates diverse libraries of fragments for virtual screening. More advanced methods like molecular dynamics-based fragmentation and quantum chemical fragmentation provide deeper insights into bond-breaking behavior, allowing for more accurate predictions of how molecules will behave under specific conditions.

When combined with optimization techniques such as Physical Programming, fragmentation becomes even more powerful. Physical Programming offers a multi-objective optimization approach, allowing researchers to define ranges of desirability for each molecular property-such as stability, solubility, and reactivity. By integrating fragmentation with this optimization framework, researchers can generate a set of molecular building blocks and recombine them in ways that balance conflicting objectives, like optimizing performance while minimizing toxicity. This hybrid approach not only enhances the efficiency of the molecular discovery process but also ensures that the resulting molecules meet complex, multi-faceted requirements.

In summary, the combination of fragmentation processes and optimization methods, like Physical Programming, offers a robust and efficient strategy for molecular design. By breaking down complex molecules into simpler fragments and using optimization to guide the recombination process, researchers can generate novel compounds with highly tailored properties for specific applications. This integration, supported by machine learning models such as CNNs, RNNs, and LSTMs, accelerates the pace of innovation and drives the development of new molecules that meet both performance and safety criteria. There are several fragmentation techniques employed in molecular discovery, each with its own unique approach to breaking down complex molecules

BRICS (Breaking of Rigid Bonds into Fragments) is a widely used method in which molecules are fragmented by breaking bonds considered to be rigid. These bonds are typically stable and do not undergo rapid conformational changes. The primary goal of BRICS is to generate fragments that are chemically stable and suitable for recombination to form novel drug-like molecules. BRICS is deterministic and follows predefined rules for fragmentation, making it a straightforward and reliable technique for fragment-based drug design. However, it does not inherently optimize for molecular properties, which means additional steps are often needed for fragment recombination and optimization.

TOP fragmentation involves breaking molecules at bonds that are likely to cause torsional strain. These bonds are typically found in flexible regions of the molecule that can undergo significant conformational changes. By breaking these bonds, the method reduces the strain and simplifies the molecule. This approach is particularly useful for designing simplified analogs or studying the flexibility of complex molecules. Unlike BRICS, TOP fragmentation focuses more on flexibility and strain rather than rigidity, providing a useful tool for studying molecular dynamics and interactions

Reactive fragmentation focuses on identifying bonds that are prone to breakage due to the presence of reactive sites, such as electrophilic or nucleophilic groups. These reactive sites are targeted in the fragmentation process, breaking bonds where chemical reactions are most likely to occur. This method is particularly valuable in the design of covalent inhibitors or for studying reactive intermediates in chemical reactions. It is often used in drug discovery to create molecules that interact with specific biological targets via covalent bonding.

Combinatorial fragmentation breaks down molecules into smaller building blocks, which are then recombined in various ways to generate new molecular structures. This approach is often used in virtual screening and fragment-based drug discovery to explore vast chemical spaces by generating diverse libraries of fragments. The recombination process allows researchers to test different combinations of fragments, which increases the chances of discovering novel bioactive compounds. Combinatorial fragmentation is particularly valuable for generating diverse compound libraries for high-throughput screening.

Radical fragmentation utilizes radical chemistry to break bonds within a molecule. The process focuses on generating radicals at specific positions, which are highly reactive and prone to bond cleavage. This technique is often used in the context of drug discovery to design molecules that interact with biological targets through radical-based reactions. Radical fragmentation can be particularly useful for studying reaction mechanisms and generating novel compounds that might not be easily accessible through traditional fragmentation methods.

Molecular dynamics-based fragmentation is a more advanced approach that utilizes simulations of molecular motion to predict how bonds will break. This method takes into account the movement of atoms and the influence of external factors like temperature and solvent, allowing for more realistic predictions of bond cleavage under specific conditions. Molecular dynamics-based fragmentation is useful for studying how molecules behave in different environments, such as during drug-receptor interactions or in biological systems, making it a powerful tool for understanding molecular flexibility and interactions.

Chemical structure similarity-based fragmentation fragments molecules by searching for known substructures or motifs that are commonly found in bioactive compounds. These substructures act as templates for generating new fragments, ensuring that the resulting fragments are likely to possess desirable properties. This approach is commonly used in cheminformatics and molecular database searches, as it helps identify molecules that are structurally similar to known drugs or bioactive compounds, facilitating lead discovery and optimization.

Natural product fragmentation focuses on breaking down molecules that are derived from natural sources, such as plants, fungi, or bacteria. This method uses the structural features found in bioactive natural products as templates for fragmenting the molecule. Natural product fragmentation is especially useful for identifying fragments that are known to have biological activity, which can be recombined to create novel drug-like compounds. It is a valuable approach in the search for new drugs, as many natural products have therapeutic properties.

Scaffold-hopping fragmentation involves replacing the core scaffold of a molecule with a different fragment while maintaining the desired biological activity. This method is used to generate novel chemical scaffolds that can still bind to the target protein but introduce structural diversity. Scaffold-hopping is particularly useful in drug discovery when trying to overcome issues such as drug resistance, as it allows researchers to explore new molecular scaffolds that retain the activity of known compounds.

Substructure search fragmentation involves identifying and fragmenting specific substructures or functional groups within a molecule. This approach is useful for focusing on key motifs that are critical for the biological activity of the compound. It can help generate fragments that are important for receptor binding or other molecular interactions, making it a targeted and efficient method for fragment-based drug discovery.

Quantum chemical fragmentation uses quantum mechanics to predict bond-breaking events based on the electronic structure of the molecule. This approach takes into account the detailed electronic interactions within the molecule, providing a highly accurate method for predicting how and where bonds will break. Quantum chemical fragmentation is particularly valuable in studying reaction mechanisms and for designing highly specific and selective drug candidates that target particular molecular features.

Connectivity-based fragmentation focuses on the connectivity of atoms and bonds within a molecule. This method identifies patterns of molecular connectivity that are significant for breaking bonds, often aiming to create fragments that retain the essential structural features of the original molecule. It is particularly useful for generating fragments with similar connectivity patterns to known drug-like molecules, facilitating lead compound discovery and optimization.

Each of these fragmentation methods serves a distinct purpose and can be chosen depending on the specific needs of the research or the drug discovery process. Fragmentation techniques like BRICS and TOP are used for structural decomposition, while more advanced methods like molecular dynamics-based fragmentation and quantum chemical fragmentation offer detailed insights into bond-breaking behavior and molecular interactions. In contrast, combinatorial and scaffold-hopping approaches are more geared toward generating novel molecules or diversifying chemical scaffolds for drug development.

Table 1, below provides a comparison of different fragmentation methods, highlighting their key features and applications in molecular discovery, from traditional rule-based approaches to more advanced techniques that offer deeper insights into molecular behavior and optimization.

TABLE 1
Comparison of Fragmentation Methods

| Fragmentation | | |
|---|---|---|
| Method | Key Features | Applications |
| BRICS | Rigid bond breaking for stable | Lead optimization, fragment-based |
| | fragments | drug design |
| TOP | Breaks based on torsional strain | Simplifying complex molecules, |
| | | designing flexible analogs |
| Reactive | Focus on chemically reactive | Covalent drug design, targeting |
| Fragmentation | sites | reactive sites in molecules |
| Combinatorial | Recombines building blocks | Virtual screening, fragment-based |
| Fragmentation | from known molecules | compound generation |
| Radical | Uses radicals to break bonds | Radical-based drug design, reaction |
| Fragmentation | | mechanism studies |
| Molecular | Breaks bonds based on molecular | Predicting behavior in different |
| Dynamics-Based | motion (thermal) | environments, receptor binding |
| Similarity-Based | Fragments based on structural | Cheminformatics, molecular |
| Fragmentation | similarity to others | database searches |
| Natural Product | Uses natural products as | Identifying bioactive fragments |
| Fragmentation | templates | from natural sources |
| Scaffold-Hopping | Replaces scaffolds to introduce | Overcoming drug resistance, |
| Fragmentation | diversity | designing novel scaffolds |
| Substructure Search | Identifies important | Finding key motifs, molecular |
| Fragmentation | substructures for fragmentation | interactions |
| Quantum Chemical | Uses quantum mechanics to | Highly accurate molecular |
| Fragmentation | predict bond breaks | predictions, reaction studies |
| Connectivity-Based | Breaks based on molecular | Identifying similar fragments, lead |
| Fragmentation | connectivity patterns | compound identification |

Target proteins play a crucial role in the development of drugs for various diseases. For cancer, proteins like EGFR (Epidermal Growth Factor Receptor) are overexpressed or mutated in cancers such as lung cancer, and inhibitors like erlotinib can block this signaling pathway. Similarly, BRAF mutations are found in melanoma and other cancers, with drugs like vemurafenib specifically targeting these mutations. In infectious diseases, HIV Protease is vital for the HIV life cycle, and protease inhibitors like ritonavir prevent the virus from maturing. For SARS-COV-2, the Main Protease (Mpro) plays a critical role in viral replication, and targeting this enzyme helps inhibit COVID-19 replication. In neurodegenerative diseases, Dopamine Receptors (e.g., D2R) are involved in Parkinson's and schizophrenia, and modulating these receptors can manage symptoms. Acetylcholinesterase, which breaks down acetylcholine, is targeted in Alzheimer's disease by inhibitors like donepezil to enhance cholinergic signaling. For cardiovascular diseases, ACE (Angiotensin-Converting Enzyme) regulates blood pressure, and ACE inhibitors are used to treat hypertension. Beta-Adrenergic Receptors (β2-AR) are targeted by beta-blockers to manage heart conditions and reduce blood pressure. In diabetes, PPARγ (Peroxisome Proliferator-Activated Receptor Gamma) regulates glucose metabolism, and drugs like pioglitazone activate this receptor to control blood sugar levels.

### SUMMARY OF THE INVENTION

The invention, Neural Optimization Platform for Molecular Discovery, is an advanced, integrated system that accelerates the process of discovering molecules with specific, tailored properties. The process begins with loading a comprehensive molecular database containing various molecular structures and their corresponding properties. The data is then cleaned to ensure accuracy and readiness for further analysis by removing inconsistencies and errors that could impact subsequent steps.

Once the data is prepared, the molecules undergo fragmentation using the BRICS method (Breaking of Rotatable Bonds and Identifying Chemical Substructures). This process involves systematically breaking down molecules at specific rotatable bonds, resulting in smaller, chemically significant fragments. These fragments retain the essential structural and functional features of the original molecules, making them easier to analyze and model. By reducing the complexity of molecular structures, fragmentation allows researchers to focus on critical substructures that influence molecular properties. The fragmented data is stored in an Excel file, ensuring it is organized and accessible for efficient tracking, analysis, and further processing.

The next step involves converting the molecular fragments into graph representations, where the atoms are treated as nodes and the bonds between them as edges. These graphs encode the molecular structure in a way that is particularly well-suited for computational analysis, capturing both local atomic environments and global connectivity. This transformation allows advanced machine learning models, such as Graph Neural Networks (GNNs), to analyze molecular interactions and predict critical properties like solubility, reactivity, and bioactivity. By leveraging the expressive power of graph-based learning, these models can uncover patterns and relationships within the molecular data that are difficult to discern using traditional techniques.

Once the graph representations are prepared, a GNN is trained on the dataset of molecular fragments. GNNs are a specialized class of machine learning models designed to process graph-structured data, making them ideal for studying molecules. The training process enables the GNN to learn intricate patterns in the data, such as how specific atomic configurations and bond types influence molecular properties. This ability to model relational data allows GNNs to predict a wide range of molecular descriptors, including physicochemical properties, biological activity, and potential toxicity. These predictions are invaluable for identifying promising molecular candidates for further exploration.

Following the GNN training phase, molecular docking simulations are performed. This computational method predicts how the molecular fragments interact with biological targets, such as enzymes or receptors. Docking simulations evaluate key parameters like binding affinity, specificity, and interaction strength, providing insights into how well a molecule fits and interacts with its target. This step helps prioritize molecules with the highest potential for therapeutic or functional applications, forming the basis for subsequent lead optimization.

The lead optimization phase is a critical step in the pipeline, where promising molecules are refined to enhance their performance. This involves improving properties such as efficacy, stability, potency, and selectivity through systematic modifications to the molecular structure. Structure-Activity Relationship (SAR) studies play a central role in this phase, analyzing the correlation between chemical structure and biological activity to identify key features that contribute to the molecule's effectiveness. By iteratively modifying the structure, researchers can optimize the molecule to achieve desired properties.

In vitro testing is conducted on optimized molecules to evaluate their biological activity under controlled conditions. Cell-based assays simulate the molecule's effects in living organisms, measuring parameters such as growth inhibition, enzyme inhibition, or other specific biological responses. Concurrently, physicochemical properties are refined to ensure optimal absorption, distribution, metabolism, and excretion (ADME) properties, which are critical for real-world applications. High-throughput screening assays assess solubility, stability, permeability, and other properties that influence the molecule's performance in biological systems.

To ensure safety, comprehensive toxicity profiling is conducted to evaluate potential cytotoxicity and genotoxicity. Advanced assay systems, including animal models and human cell lines, are used to assess the molecule's safety profile. This rigorous process minimizes the risk of adverse effects and ensures that the molecule meets regulatory standards for further development.

Throughout the optimization process, machine learning techniques, particularly GNNs, are integrated to enhance efficiency and accuracy. GNNs predict molecular behavior based on the relationships learned during training, guiding researchers in selecting and refining promising candidates. The combination of traditional molecular modeling approaches and cutting-edge machine learning significantly accelerates the discovery and development of novel molecules with tailored properties.

This holistic approach, powered by the Neural Optimization Platform for Molecular Discovery, represents a transformative advancement in fields such as pharmaceuticals, materials science, and beyond. By integrating molecular fragmentation, graph-based learning, docking simulations, and lead optimization into a seamless workflow, this platform not only speeds up innovation but also enables the discovery of highly specialized molecules. These advancements are crucial for addressing complex challenges in drug development, materials innovation, and other domains, driving progress and enabling breakthroughs in science and technology.

### DETAILED DESCRIPTION OF THE INVENTION

The Neural Optimization Platform for Molecular Discovery is an advanced, integrated computational system designed to accelerate the discovery of novel molecules with specific, tailored properties. The platform seamlessly integrates traditional molecular modeling methods with modern machine learning approaches to enhance the speed and accuracy of molecular discovery. This detailed description outlines the key components and processes involved in the platform, highlighting how it optimizes the molecular discovery workflow.

The first step in the molecular discovery process is to load a molecular database that contains a large collection of molecules, each with associated properties and characteristics. These molecules may come from a variety of sources, including publicly available datasets, proprietary collections, or experimental results. The molecular database is the foundation upon which the entire discovery process is built.

The database is loaded into the platform in a structured format, typically as a file containing molecular structures, chemical information (such as molecular weight, charge, and functional groups), and biological activity data (e.g., binding affinity or toxicity). Ensuring the data is accurate and properly formatted is critical, as it directly influences the results of downstream analyses.

Once the molecular database is loaded, the next step is data cleaning. Raw molecular data often contains inconsistencies, errors, or missing information, which can hinder the performance of machine learning models and computational simulations. Data cleaning involves identifying and correcting these issues, such as removing duplicate entries, correcting structural inaccuracies, and filling in missing values.

This process also includes the normalization of the data to ensure consistency in units and formats, making the data ready for further analysis. Proper data cleaning ensures that the analysis performed in subsequent stages is reliable and reproducible.

After cleaning the data, the next step is to break down the molecules into smaller, more manageable fragments using the BRICS (Breaking of Rotatable Bonds and Identifying Chemical Substructures) method. BRICS is a well-established fragmentation technique that focuses on identifying rotatable bonds in the molecule and splitting them at these locations, which often leads to the generation of smaller fragments that maintain significant chemical functionality.

This fragmentation approach is critical for understanding the fundamental components of a molecule and how they contribute to the overall behavior and properties of the compound. By fragmenting molecules into smaller pieces, the platform is able to analyze individual components in isolation, which can reveal important insights into molecular behavior and interactions.

The fragmented data is then stored in a structured format, such as an Excel file or database, allowing for easy tracking, retrieval, and further analysis.

Once the molecules are fragmented, the next step is to convert the molecular structures, including the fragments, into graph representations. In this representation, molecules are treated as graphs where atoms are nodes and bonds between atoms are edges. This graph-based approach is crucial for utilizing machine learning models, particularly Graph Neural Networks (GNNs).

Graph representations capture the inherent relationships between atoms and bonds, which are crucial for understanding molecular interactions. This transformation makes the data suitable for input into advanced machine learning models that can analyze and predict molecular properties based on the structure and connectivity of the graph

The converted graph representations are then used to train Graph Neural Networks (GNNs). GNNs are a class of machine learning models designed to process graph-structured data. These networks excel at learning complex, non-linear relationships between the nodes (atoms) and edges (bonds) in a molecular graph. By training the GNN with a large dataset of molecular graphs and their corresponding properties, the model learns to predict molecular descriptors that characterize the molecule's behavior, such as solubility, toxicity, reactivity, and bioactivity.

GNNs are particularly powerful in molecular discovery because they can capture the spatial and functional relationships between atoms and predict how these interactions influence the molecule's overall properties. Through supervised learning, the GNN is optimized to minimize prediction errors, allowing it to accurately predict molecular properties for unseen molecules.

Once the GNN has predicted molecular descriptors, molecular docking simulations are performed to assess how the predicted molecules or fragments interact with potential biological targets. Molecular docking involves computationally simulating the binding of a molecule to a target, such as a receptor, enzyme, or protein. This process helps determine how well a molecule fits into a target's binding site and predicts its affinity and specificity for that target.

Molecular docking provides valuable insights into the behavior of molecules within biological systems. It allows researchers to evaluate how well a compound might function in a given biological context, which is essential for identifying promising drug candidates or materials with specific properties.

Docking simulations are typically followed by scoring the binding interactions, where the predicted binding affinity is calculated to determine the strength of the interaction between the molecule and the target. This step allows researchers to rank molecules based on their predicted efficacy and prioritize those that show the most promise.

Finally, the most promising molecules identified through molecular docking simulations undergo lead optimization. Lead optimization is a process that refines molecular candidates to improve their properties, such as potency, selectivity, stability, and pharmacokinetics, while reducing toxicity and other undesirable characteristics. This step often involves iterating on the molecular structure, making targeted modifications to improve performance.

Lead optimization can be done using a combination of computational techniques and experimental validation. The Neural Optimization Platform for Molecular Discovery uses machine learning models, like GNNs, in conjunction with traditional optimization techniques, to identify the most optimal molecular modifications. This hybrid approach ensures that the final candidates meet the specific performance criteria required for real-world applications, such as drug development, material science, or environmental applications

The Neural Optimization Platform for Molecular Discovery represents a cutting-edge approach that integrates traditional molecular modeling with advanced machine learning techniques to accelerate the discovery and optimization of molecules. By combining methods such as molecular fragmentation, graph neural networks, molecular docking, and lead optimization, the platform offers a powerful and efficient solution for designing molecules with specific, tailored properties.

This invention significantly enhances the molecular discovery process by automating many of the tasks traditionally carried out manually, improving the speed and accuracy of identifying promising molecular candidates. Whether used in pharmaceuticals, material science, or other industries, the Neural Optimization Platform for Molecular Discovery has the potential to revolutionize how new molecules are discovered, designed, and optimized for a wide range of applications.

### Advantages of the Invention

The Neural Optimization Platform for Molecular Discovery offers several transformative advantages that significantly enhance the molecular discovery process. One of the most prominent benefits is the acceleration of the discovery timeline. Traditional methods often involve time-consuming and resource-intensive trial-and-error experiments, but by leveraging machine learning and computational techniques, the platform automates many steps in the process. This enables researchers to rapidly identify promising molecular candidates without the need for extensive laboratory testing, dramatically shortening the time required to bring new molecules to market.

In addition to speeding up the discovery process, the platform enhances the accuracy and precision of predictions. Traditional molecular modeling techniques, such as molecular docking or fragmentation methods, are often limited in their ability to capture the complex interactions within large molecules. However, the use of Graph Neural Networks (GNNs) allows the platform to model molecular interactions with greater accuracy. GNNs are particularly effective in learning the intricate, non-linear relationships between atoms and bonds, resulting in more reliable predictions of molecular properties such as solubility, toxicity, and bioactivity.

Another key advantage of the platform is its scalability and ability to handle high throughput. Unlike traditional experimental methods that are constrained by the need for individual testing of each compound, the platform can process vast chemical spaces in parallel. This is made possible by the graph-based representations of molecules, which are ideal for machine learning models. As a result, the platform is capable of screening thousands or even millions of molecules at once, making it highly efficient in exploring large molecular libraries or testing various modifications to a single compound.

Furthermore, the platform significantly reduces experimental costs. Traditional molecular discovery relies heavily on laboratory-based synthesis and testing, which can be costly and time-consuming. By predicting molecular properties and behaviors computationally, the Neural Optimization Platform minimizes the need for extensive laboratory testing. The platform's ability to simulate molecular docking and predict molecular descriptors helps researchers focus their experimental efforts on the most promising candidates, reducing the number of compounds that need to be synthesized and tested.

The platform also offers the ability for targeted molecular design. Unlike conventional molecular discovery methods that often involve a trial-and-error approach, the platform allows researchers to design molecules with specific, predefined properties. Whether the goal is to create molecules with enhanced bioactivity, improved selectivity, or specific stability characteristics, the platform's machine learning models can optimize molecular structures to meet these criteria. This results in molecules that are better suited for real-world applications, whether in drug development, materials science, or environmental solutions.

Additionally, the integration of traditional molecular modeling with advanced machine learning techniques provides a powerful hybrid approach. Methods like molecular docking and BRICS fragmentation are well-established, but they often struggle to model complex, non-linear relationships. By combining these traditional methods with the predictive power of GNNs, the platform improves the accuracy of predictions and provides a more comprehensive understanding of molecular behavior. This integration ensures that the platform benefits from the strengths of both computational methods, offering a more efficient and reliable discovery process.

Another critical advantage is in the area of lead optimization. The platform excels in refining molecular candidates to improve their desired properties, such as potency, stability, and selectivity, while minimizing undesirable attributes like toxicity or off-target effects. By using machine learning models in combination with traditional optimization techniques, the platform ensures that the final candidates meet performance criteria for real-world applications. This iterative optimization process ensures that the compounds are not only promising in theory but also effective and suitable for further development and commercialization.

Lastly, the flexibility and versatility of the platform make it applicable to a wide range of industries and research fields. Whether applied to drug discovery, materials development, or environmental solutions, the platform can be tailored to meet the specific needs of each domain. For example, in drug discovery, the platform can aid in designing molecules that bind with high specificity to therapeutic targets, while in material science, it can predict the properties of polymers, nanomaterials, or other substances with precise mechanical, thermal, or electrical characteristics.

In conclusion, the Neural Optimization Platform for Molecular Discovery offers a comprehensive and powerful approach to molecular design. By combining machine learning with traditional molecular modeling techniques, the platform accelerates the discovery process, improves accuracy, reduces costs, and enables targeted molecular design. Its scalability, flexibility, and ability to optimize leads make it a valuable tool in various industries, from pharmaceuticals to materials science, driving innovation and enabling the creation of molecules with tailored properties for specific applications.

### BRIEF DESCRIPTION OF THE DRAWINGS

FIG. 1 illustrates the various methods available for accessing ChEMBL data, offering flexible access through multiple formats and databases: 1, MySQL, 2, CSV (Comma-Separated Values), 3, SQLite, 4, Oracle Database, 5, Excel (XLS), 6, JSON (JavaScript Object Notation), 7, RDF (Resource Description Framework), and 8. the ChEMBL Web Interface. Each of these methods provides access to ChEMBL's comprehensive chemical and bioactivity data, supporting a wide range of applications in research and computational analysis.

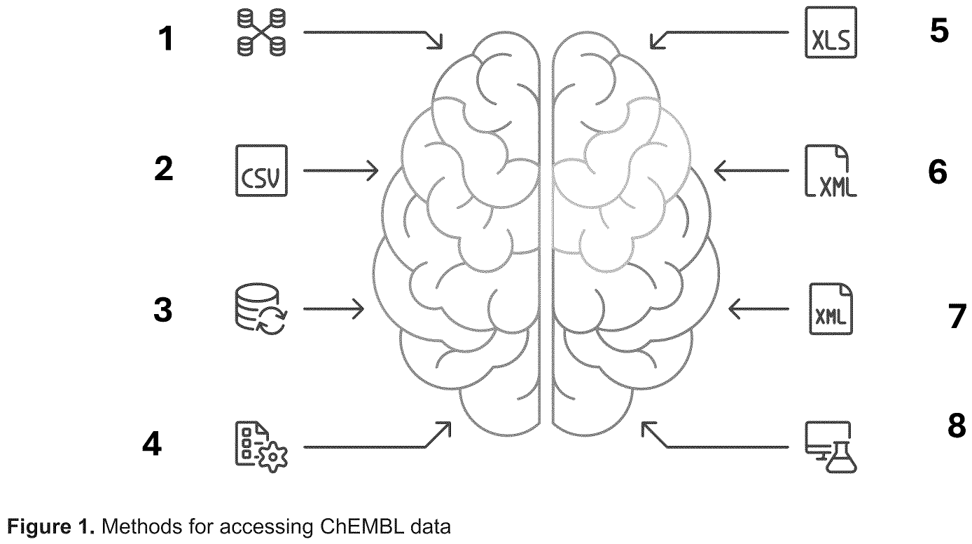

FIG. 2 presents the different types of Molecular Fingerprints and their applications: 1, Substructure Fingerprints is ideal for representing smaller molecules, such as those commonly found in pharmaceuticals. 2, Atom-Pair Fingerprints is optimized for analyzing larger, more complex molecules like peptides.

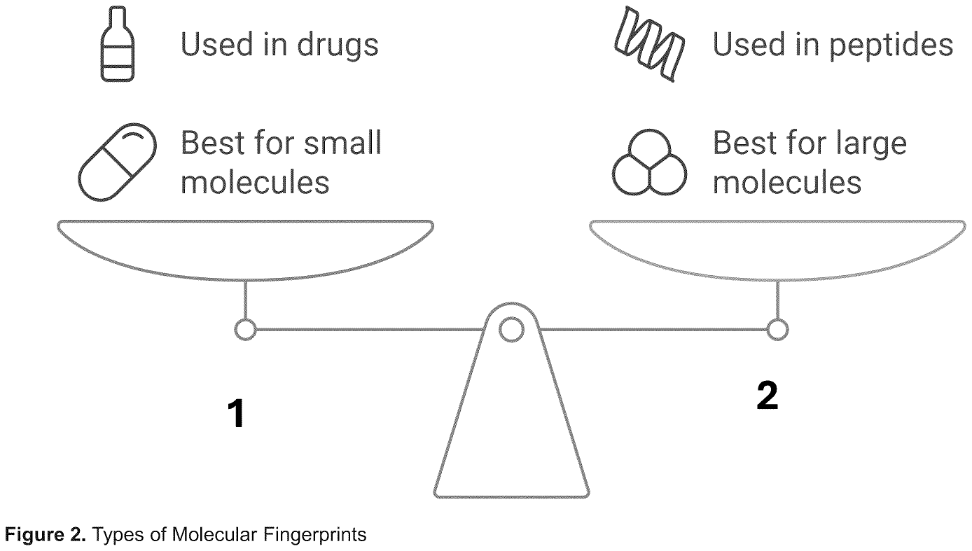

FIG. 3 provides an overview of the 1, ChEMBL Molecular Data categories consisting of 2, Biological Data, including targets and bioactivities, 3, Clinical Data, contains the maximum clinical phase achieved by a compound, 4, Drug-likeness, including properties such as hydrogen bond acceptors (HBA), donors (HBD), and violations of Lipinski's Rule of Five. 5, is Basic Information such as Names, synonyms, and type of compound. 6, is Physical Properties such as Molecular weight, AlogP, polar surface area. 7, is Structural Data including Molecular formula, SMILES notation, and InChI Key.

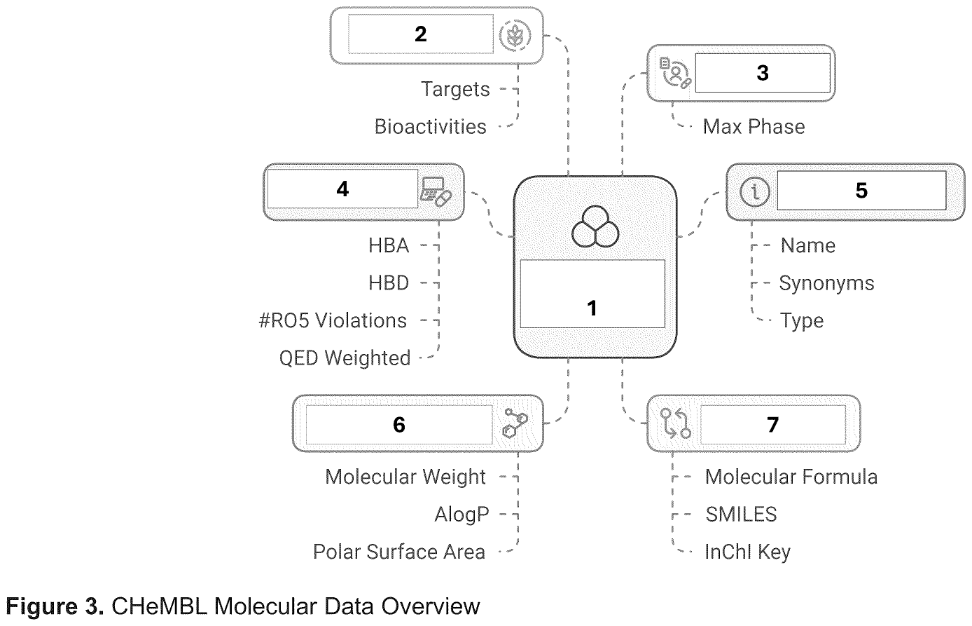

FIG. 4 explains the Data Preparation Process for molecular fingerprints, including, 1, upload from Database. Molecular data is imported from a source like ChEMBL. 2, is data Inspection, data is reviewed for quality and consistency. 3, Prune Zero Values: Rows or columns with zero or missing values are removed. 4, Transform to Fingerprints: Molecular structures are transformed into binary fingerprints, representing the molecular features for input into the model.

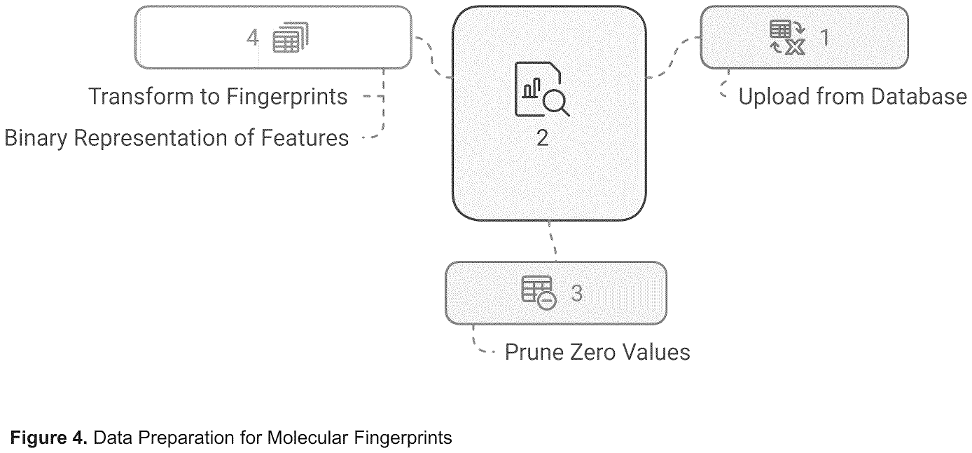

FIG. 5 illustrates the key steps in building and deploying a Graph Neural Network (GNN) model for molecular discovery. The process begins with 1, Data Preparation, where molecules are converted into graph representations, and features are extracted. This is followed by 2, Model Design, where the GNN architecture is built, and message passing is performed to capture the relationships between the nodes and edges of the graph. Once the model is designed, it undergoes 3, Training, where it is optimized using loss functions and regularization techniques to improve its performance. After training, the 4, Evaluation phase assesses the model's performance and tunes hyperparameters to refine its accuracy. Finally, in the 5, Deployment stage, the model is used for predictions and its robustness is analyzed, allowing it to be applied in real-world scenarios for tasks like drug discovery or materials innovation. Each of these steps plays a critical role in ensuring the model's effectiveness and efficiency in molecular optimization.

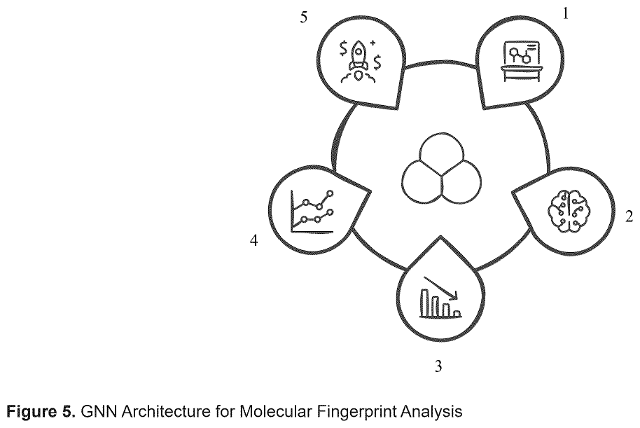

FIG. 6 outlines the process flow for working with SMILES data in molecular fragmentation and property prediction. The first step is 1, Verify SMILES, where the SMILES string is checked to ensure it can be converted into a valid molecule. Once the SMILES string is verified, the next step is 2, Decompose using BRICS, where the molecule is fragmented by breaking rigid bonds to create smaller fragments. 3, Timeout Handling follows, ensuring that the fragmentation process doesn't run indefinitely, preventing delays and inefficiencies. After fragmentation, the 4, Process SMILES Data step applies the fragmentation to molecules listed in an Excel file, allowing for batch processing of multiple compounds. Finally, in the 5, Save Results step, the fragmented data and predicted properties are output, ensuring that the results are stored for further analysis or application in drug discovery or materials design. This structured approach enables efficient handling of molecular data, making it suitable for use in various optimization workflows.

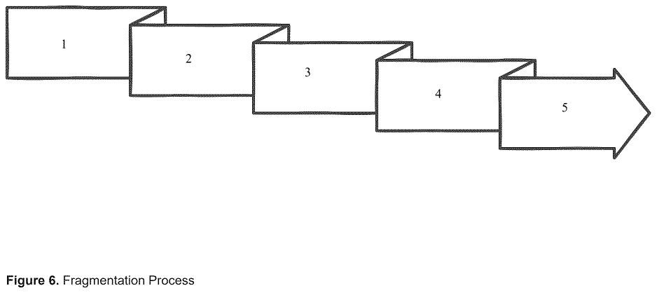

FIG. 7 outlines the Molecular Analysis and Discovery Process, a step-by-step flow of activities typically followed in molecular research and drug discovery. The process begins by 1, loading a molecular database, which contains the chemical compounds to be analyzed. Once the data is loaded, the next step is to 2, clean the data, ensuring it is in a usable format for further processing. The following step involves 3, fragmentation with BRICS, where molecules are fragmented into smaller, more manageable components using the BRICS algorithm, facilitating docking and further analysis. After fragmentation, the data is 4, saved to a file, such as an Excel file, for easy retrieval and management. The next stage is 5, fragment docking and ranking, where molecular fragments are docked, and their binding affinities or other relevant properties are used to rank them. 6, Converting SMILES to graph representations follows, where the SMILES (Simplified Molecular Input Line Entry System) representations of molecules are converted into graph-based structures to support machine learning-based analysis. 7, Training a graph neural network comes next, where the network is trained to understand relationships between atoms, bonds, and other molecular features. Using this trained model, 8, molecular descriptors, such as log P and molecular weight, are predicted to assist in property analysis. Following this, 9, molecular docking simulations are performed to explore how well molecules interact with potential target sites, such as proteins. Finally, the process concludes with 10, lead optimization, where the most promising “lead” compounds are optimized to improve their properties, making them suitable for use in drug development. This comprehensive process integrates various stages of molecular research to streamline the discovery and optimization of potential drug candidates.

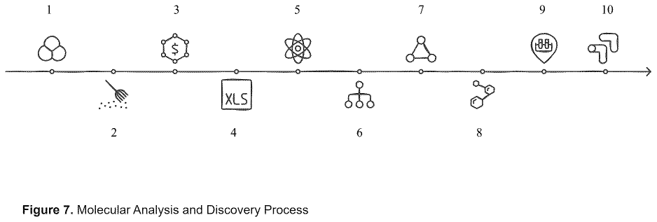

FIG. 8 illustrates the step-by-step process for 7, molecular docking, which is used to predict the interaction between a molecule (such as a drug) and its target protein. The process begins with 1, Preparing Molecules, where SMILES strings are converted to 3D structures, and molecules are batch-prepared for docking. Next, in 2, Preparing the Target Protein, the target protein's PDB file is obtained, and the binding site is defined to guide the docking process. The core step is 3, Performing Docking, which involves choosing appropriate docking software, preparing the necessary input files, and running the docking simulations to predict how the molecules will interact with the protein. After docking, the 4, Analysis of Results phase extracts binding scores, ranks the molecules based on their predicted affinity, and visualizes the interactions between the molecules and the protein. Once the analysis is complete, the 5, Ranked Results are outputted in a summary table, highlighting key interactions and providing a clear ranking of the molecules for further investigation. Finally, 6, Post-Docking Refinement involves performing molecular dynamics (MD) simulations to validate the stability of the binding interactions, ensuring that the results are robust and reliable for subsequent stages of drug development or materials design. This workflow effectively combines various steps to predict and optimize molecular interactions, making it crucial for fields like drug discovery and materials science.

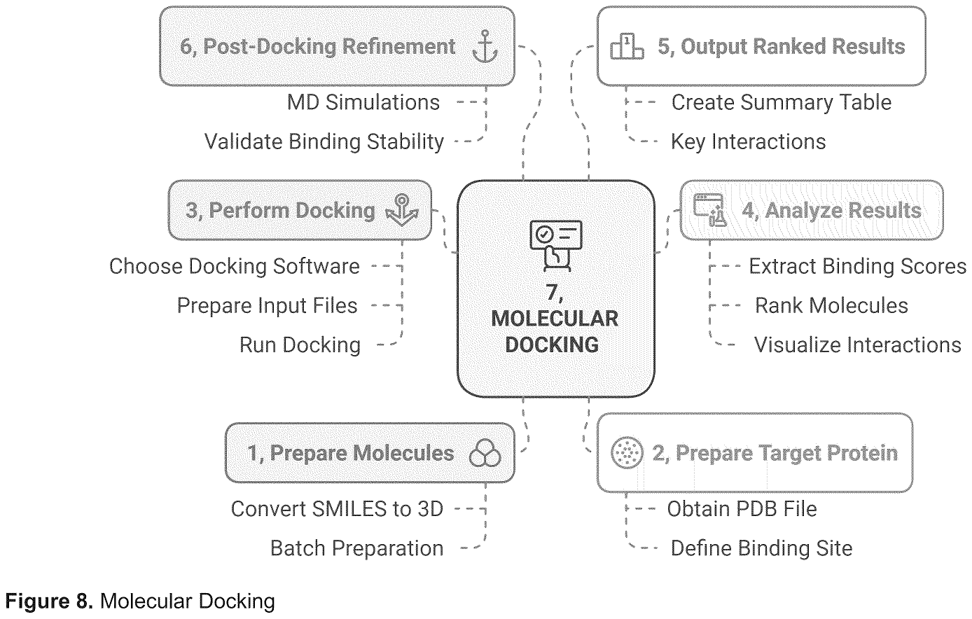

FIG. 9 represents the three-dimensional structure of the Protein Kinase A (PKA) catalytic subunit (1TW7), which is a target protein used for molecular docking. The structure, known as the Wide Open 1.3A Structure of a Multi-drug-Resistant HIV-1 Protease, presents a novel drug target. The protein is depicted in a ribbon diagram, visually representing the secondary structure elements. Key features of the structure are highlighted as follows: The green and orange ribbons represent the two distinct domains of the PKA catalytic subunit, divided into the catalytic and regulatory domains. These colored regions correspond to different areas within the protein, potentially involved in interactions or catalysis. Purple spheres in the structure likely represent critical metal ions or cofactors necessary for PKA's enzymatic activity. Magnesium ions or other metal cofactors play a key role in stabilizing the substrate and facilitating the transfer of phosphate groups, essential for the enzyme's function. PKA is crucial for cellular signaling, regulating various processes such as cell growth, metabolism, and gene expression through phosphorylation, where phosphate groups are transferred to specific target proteins. The PKA structure is composed of both a regulatory subunit and a catalytic subunit, with the catalytic subunit responsible for the enzymatic activity. The function of the PKA catalytic subunit is to phosphorylate target proteins in response to cyclic AMP (cAMP) signals. In the absence of CAMP, the regulatory subunits inhibit the catalytic subunit. Upon CAMP binding, the regulatory subunit releases the catalytic subunit, enabling its enzymatic activity. The structural significance of the ribbon diagram highlights various loops, helices, and strands that contribute to the protein's functional properties, facilitating its interaction with other cellular components and its role in signal transduction pathways. The biological relevance of understanding PKA's structure is immense, particularly for the development of therapeutic agents targeting diseases associated with abnormal kinase activity, such as cancers and heart diseases. The interaction between the regulatory and catalytic subunits is a key focus for drug design, offering potential targets for therapeutic interventions.

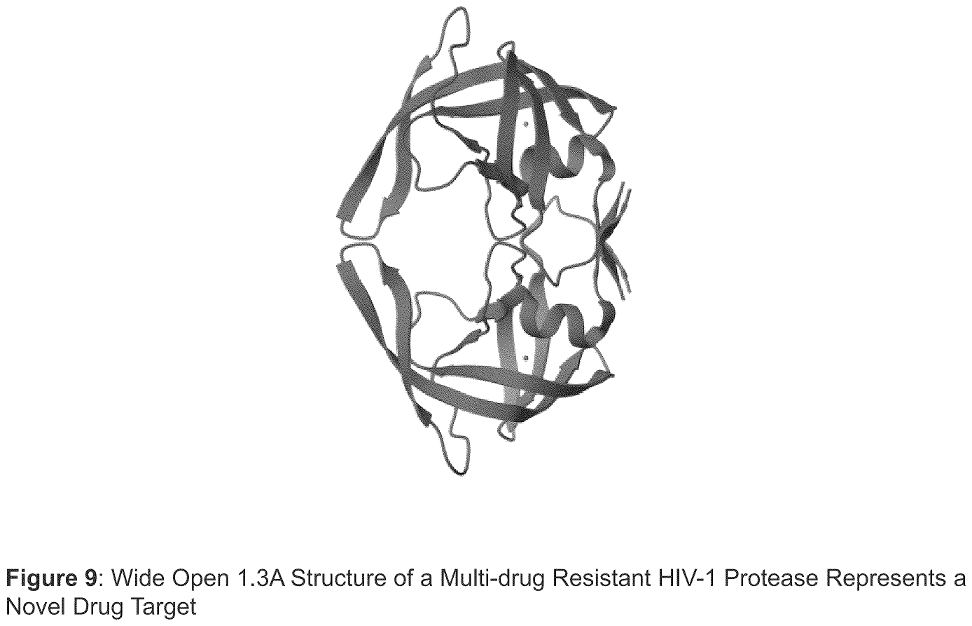

### EXAMPLE. DISCOVERING A BIODEGRADABLE MOLECULE FOR DRUG DELIVERY

### Step 1: Data Collection and Preparation

The process begins by collecting molecular data from a source like the ChEMBL database. ChEMBL is a manually curated database of bioactive molecules with drug-like properties. It brings together chemical, bioactivity and genomic data to aid the translation of genomic information into effective new drugs. A protein database consisting of 22,874 compounds was used as the baseline for this example. Initially it was in a csv file, which was subsequently converted to an excel file for ease of use. Table 1 shows the format of the Protein Excel Database. The Excel database detailed molecular and chemical data from ChEMBL, including properties for specific compounds or proteins. Here's a breakdown of key columns:
1. ChEMBL ID: Unique identifier for each compound or protein in the ChEMBL database.
2. Name: The name of the compound or protein.
3. Synonyms: Alternative names or identifiers for the compound, providing flexibility for searches.
4. Type: Classifies the molecule as a protein, small molecule, etc.
5. Max Phase: Refers to the highest clinical trial phase that the compound has reached, indicating how advanced it is in terms of drug development.
6. Molecular Weight: The weight of the molecule, crucial for predicting solubility, permeability, and drug-like properties.
7. Targets: Refers to biological targets, such as proteins, that the compound interacts with.
8. Bioactivities: Represents bioactivity data, measuring the compound's effectiveness in interacting with its target.
9. AlogP: A property measuring lipophilicity, which is important for drug absorption and distribution.
10. Polar Surface Area: A measure of the surface area occupied by polar atoms (e.g., oxygen, nitrogen), influencing permeability and solubility.
11. HBA (Hydrogen Bond Acceptors): The number of atoms in the molecule that can accept hydrogen bonds, impacting solubility and interactions with biological targets.
12. HBD (Hydrogen Bond Donors): The number of atoms that can donate hydrogen bonds, similarly affecting solubility and target interactions.
13. #RO5 Violations: Indicates if the compound violates any of Lipinski's “Rule of Five,” which predicts a molecule's drug-likeness.
14. #Rotatable Bonds: The number of bonds that can freely rotate, which can influence molecular flexibility and bioavailability.
15. Structure Type: Classifies whether the molecule is inorganic, organic, or a mixture of both.
16. Heavy Atoms: Number of non-hydrogen atoms, which contributes to molecular complexity and potency.
17. InChI Key/SMILES: These are text representations of the chemical structure of the molecule, useful for cheminformatics and computational analysis.

TABLE 2
Protein Excel Database - Overview

| | | | | | | | Polar | | | |
|---|---|---|---|---|---|---|---|---|---|---|
| ChEMBL | | Max | Molecular | | | | Surface | | | #RO5 |
| ID | Type | Phase | Weight | Targets | Bioactivities | AlogP | Area | HBA | HBD | Violations |
| CHEMBL2 [symbol] | Protein | 2 | 3013.6 | | | | | | | |
| CHEMBL1 [symbol] | Protein | | 1856.51 | | | | | | | |
| CHEMBL2 [symbol] | Protein | | 781.97 | 1 | 2 | −0.48 | 278.38 | 11 | 10 | 3 |
| CHEMBL2 [symbol] | Protein | | 917.02 | 1 | 2 | −4.81 | 417.87 | 15 | 16 | 3 |
| CHEMBL2 [symbol] | Protein | 2 | 2469.45 | | | | | | | |
| CHEMBL2 [symbol] | Protein | 2 | 588.58 | | | −4.95 | 327.66 | 10 | 11 | 2 |
| CHEMBL1 [symbol] | Protein | | 368.48 | | | −0.9 | 142.91 | 5 | 4 | 0 |
| CHEMBL3 [symbol] | Protein | | 909.99 | 1 | 5 | −4.18 | 408.1 | 14 | 14 | 3 |
| CHEMBL3 [symbol] | Protein | | 1335.53 | | | | | | | |

[symbol]

indicates data missing or illegible when filed

In this case, the data is preprocessed and filtered to ensure high-quality input for the model. Missing values are removed, and molecular descriptors are transformed into molecular fingerprints, which are compact binary representations that capture structural information about the molecules. See Table 3.

TABLE 3
Protein Excel Database - Filtered Data

| Molecular | |
|---|---|
| Weight | smiles |
| 781.97 | CSCC[C@H](NC(═O)[C@@H](NC(═O)[C@H](C)NC(═O)[C@H](CC(C)C)NC(═O)[C@H](C)NC(═O)[C@H]( [symbol] |
| 917.02 | CSCC[C@H](NC(═O)[C@H](Cc1cnc[nH]1)NC(═O)[C@H](CO)NC(═O)[C@H](CO)NC(═O)[C@H](Cc1ccc(O [symbol] |
| 588.58 | N═C(N)NCCC[C@@H](NC(═O)[C@@H]1CCCN1C(═O)[C@H](CC(═O)O)NC(═O)[C@@H](CO)NC(═O)[C@ [symbol] |

[symbol]

indicates data missing or illegible when filed

### Step 2: SMILES Data Fragmentation

The next step in the process involves breaking down the molecules into smaller, more manageable fragments. This is achieved using the BRICS method, which stands for Breaking of Rotatable Bonds and Identifying Chemical Substructures. BRICS focuses on identifying the rotatable bonds within a molecule and splitting the molecule at these bonds, thereby generating smaller fragments that are easier to analyze and manipulate. The SMILES notation of each molecule is processed, and the molecule is decomposed into these smaller fragments based on the identified rotatable bonds. The resulting fragments are then saved into an Excel file named fragmented_data.xlsx, which contains the new smaller units of the original molecules. This fragmentation process makes it easier to handle complex molecules and is a crucial step for subsequent computational analyses.

Once the molecules are fragmented, they undergo molecular docking simulations. Docking predictions are used to simulate how the fragments will interact with biological targets such as proteins or enzymes. During this step, each fragment is placed into the binding site of the biological target, and the interaction between them is simulated. The fragments are then ranked based on their docking scores, which reflect their binding affinity with the target. Fragments with higher scores are considered to have a better binding potential and are selected for further optimization or testing. This ranking helps prioritize the most promising fragments for future exploration.

TABLE 4
FRAGMENTS Database - Filtered Data

| ChEMBL ID | fragments |
|---|---|
| CHEMBL2103941 | [‘[1*]C(═O)[C@@H]([4*])C(C)C, ‘[1*]C(═O)C[4*]’, ‘[5*]N1CCC[C@H]1[13*]’, |
| | ‘[4*][C@H](C(N)═O)C(C)C, ‘[1*]C(═O)[C@@H]([4*])CCC[4*]’, ‘[1*]C(═O)[C@H](N)CO’, |
| | ‘[1*]C(═O)[C@H]([4*])CCC[4*]’, ‘[16*]c1ccccc1’, ‘[14*]c1c[nH]cn1’, |
| | ‘[1*]C(═O)[C@@H]([4*])CCCCN’, ‘[16*]c1ccc(O)cc1’, ‘[5*]NC(═N)N’, |
| | ‘[1*]C(═O)[C@@H]([4*])CO’, ‘[1*]C(═O)[C@@H]([4*])CCC(═O)O’, ‘[5*]N[5*]’, |
| CHEMBL1229044 | [‘[1*]C(═O)[C@@H]([4*])C(C)C, ‘[5*][N+](C)(C)C, ‘[1*]C(═O)C[4*]’, |
| | ‘[1*]C(═O)[C@@H]([4*])CCCC[4*]’, ‘[16*]c1ccccc1’, ‘[1*]C(═O)[C@@H]([4*])C[8*]’, |
| | ‘[4*][C@@H](CC(C)C)C(N)═O’, ‘[16*]c1c[nH]c2ccccc12’, ‘[1*]C(═O)[C@@H]([4*])C, |
| | ‘[1*]C(═O)[C@@H]([4*])[C@@H](C)CC, ‘[1*]C(═O)[C@@H]([4*])CCCCN’, |
| | ‘[1*]C(═O)[C@@H](N)CCCC[4*]’, ‘[5*]N[5*]’, ‘[1*]C(═O)[C@@H]([4*])CC(C)C] |
| CHEMBL2425403 | [‘[1*]C(═O)[C@@H](N)CC(C)C, ‘[11*]SC, ‘[1*]C(═O)[C@@H]([4*])C[8*]’, |
| | ‘[1*]C(═O)[C@@H]([4*])C, ‘[4*]CC[C@H]([4*])C(═O)O’, ‘[1*]C(═O)[C@@H]([4*])[C@@H](C)O’, |
| | ‘[16*]c1ccc(O)cc1’, ‘[5*]N[5*]’, ‘[1*]C(═O)[C@@H]([4*])CC(C)C] |
| CHEMBL2425396 | [‘[4*]CCC[C@H]([4*])C(═O)O’, ‘[1*]C(═O)[C@@H](N)C[8*]’, ‘[16*]c1ccc(O)cc1’, ‘[11*]SC, |
| | ‘[1*]C(═O)[C@@H]([4*])C[8*]’, ‘[14*]c1cnc[nH]1’, ‘[5*]NC(═N)N’, ‘[1*]C(═O)[C@@H]([4*])CO’, |
| | ‘[1*]C(═O)[C@@H]([4*])CC[4*]’, ‘[5*]N[5*]’] |
| CHEMBL2103901 | [‘[4*][C@@H](CCCCN)C(═O)O’, ‘[1*]C(═O)[C@@H](N)CCCCN’, ‘[1*]C(═O)[C@@H]([4*])CCCCN’, |
| | ‘[5*]N[5*]’, ‘[1*]C(═O)[C@@H]([4*])CC(C)C] |
| CHEMBL2304033 | [‘[1*]C(═O)[C@H]([4*])CO’, ‘[4*CCC[C@@H]([4*])C(═O)O’, ‘[5*]N1CCC[C@H]1[13*]’, |
| | ‘[1*]C(═O)[C@@H]([4*])CC(═O)O’, ‘[1*]C([6*])═O’, ‘[5*]NC(═N)N’, ‘[5*]N[5*]’, |
| | ‘[1*]C(═O)[C@@H](N)CC(═O)O’] |
| CHEMBL1191337 | [‘[4*][C@H](C═O)CCCN═C(N)N’, ‘[1*]C(═O)C[4*]’, ‘[5*]N[5*]’, ‘[13*][C@H]1CCCCN1’, |
| | ‘[1*]C([6*])═O’, ‘[5*]N([5*])[5*]’, ‘[4*]CCC] |

Step 3: In this step the FRAGMENT Dataset is used and SMILES strings are represented into graph representations. The molecular data is first cleaned, removing any rows with missing SMILES values. Then, a function is defined to convert each molecule (represented as a SMILES string) into a graph structure suitable for machine learning, where atoms are nodes and bonds are edges. This process allows the use of Graph Neural Networks (GNNs) for further analysis, such as predicting molecular properties or performing docking simulations. The process begins by mounting Google Drive to access files stored on it for further processing. It then installs several essential Python libraries, such as RDKit, pandas, TensorFlow, PyTorch Geometric, and torchmetrics. These libraries are used for handling molecular data, performing machine learning tasks, and building neural network models. After setting up the environment, the notebook proceeds to load molecular data from an Excel file, which contains SMILES (Simplified Molecular Input Line Entry System) representations of molecules. The data is cleaned by removing any rows with missing or empty SMILES values, and the SMILES column is converted into a string format for further analysis. The notebook also defines a function, molecule_to_graph (smiles), which converts each molecule represented by a SMILES string into a graph format using RDKit. This function generates node features representing atoms (such as atomic number, degree, formal charge, and hybridization) and edge features representing bonds (such as bond type, conjugation, and aromaticity). The graph structure is created using PyTorch Geometric's Data class, which organizes the atomic and bond information into a format suitable for Graph Neural Networks (GNNs). This transformation from SMILES to graph representations enables the application of GNNs for predicting molecular properties, performing docking simulations, or other computational analyses related to molecular discovery.

This process begins with mounting Google Drive and installing necessary libraries like rdkit, pandas, tensorflow, torch-geometric, and torchmetrics. These libraries are commonly used for molecular data analysis and machine learning tasks. Here's an overview of what each section does:
1. Mount Google Drive:
   The notebook starts by mounting Google Drive using drive.mount( ), which allows access to files stored in Google Drive for further processing.
2. Installing Required Libraries:
   Various Python libraries such as RDKit, pandas, TensorFlow, and PyTorch Geometric are installed. These are essential for handling molecular data, building neural networks, and conducting machine learning tasks.
3. Importing Libraries:
   The notebook imports various libraries needed for data handling (like pandas and numpy), neural network model building (like torch and torch geometric), and molecular chemistry (like RDKit and rdmolops).
4. Loading Molecular Data:
   The notebook defines the path to an Excel file containing molecular data, which includes a column for SMILES (Simplified Molecular Input Line Entry System) notation of molecules.
   The file is read into a pandas DataFrame, and any rows with missing or empty SMILES values are dropped. The SMILES column is then converted into a string format for further processing.
5. Converting Molecules to Graph Representations:
   The function molecule_to_graph (smiles) is defined to convert SMILES strings into graph representations using RDKit. Each molecule is converted into a graph where:
      Nodes represent atoms, with features like atomic number, degree, formal charge, and hybridization.
      Edges represent bonds between atoms, with features such as bond type, conjugation, and aromaticity.
   The graph is created using PyTorch Geometric's Data class, which stores the atomic features, bond features, and edge indices for the graph.

TABLE 5
GNN Predictions for Defragmented SMILES

| Molecular_Weight | HBA | HBD | Rotable_Bonds | Heavy_Atoms | TPSA | Ro5_Viola | smiles |
|---|---|---|---|---|---|---|---|
| 2662.9 | 34.5 | 37.8 | 84.7 | 189.9 | 1054.3 | 3.5 | [1*]C(═O)[C@@H]([4*])C(C)C |
| 2786.3 | 36.1 | 39.6 | 88.7 | 198.8 | 1103.3 | 3.7 | [1*]C(═O)C[4*] |
| 2472.5 | 32.0 | 35.0 | 78.6 | 176.3 | 978.7 | 3.2 | [5*]N1CCC[C@H]1[13*] |
| 2427.2 | 31.5 | 34.4 | 77.2 | 173.1 | 960.7 | 3.1 | [4*][C@H](C(N)═O)C(C)C |
| 2717.5 | 35.2 | 38.6 | 86.5 | 193.8 | 1076.0 | 3.6 | [1*]C(═O)[C@@H]([4*])CCC[4*] |
| 2220.7 | 28.8 | 31.3 | 70.5 | 158.3 | 878.7 | 2.8 | [1*]C(═O)[C@H](N)CO |
| 2717.5 | 35.2 | 38.6 | 86.5 | 193.8 | 1076.0 | 3.552 | [1*]C(═O)[C@H]([4*])CCC[4*] |
| 2304.5 | 29.9 | 32.5 | 73.2 | 164.3 | 911.9 | 2.928 | [16*]c1ccccc1 |
| 2141.6 | 27.8 | 30.1 | 68.0 | 152.7 | 847.2 | 2.681 | [14*]c1c[nH]cn1 |
| 2449.5 | 31.7 | 34.7 | 77.9 | 174.7 | 969.5 | 3.147 | [1*]C(═O)[C@@H]([4*])CCCCN |
| 2184.3 | 28.3 | 30.8 | 69.4 | 155.7 | 864.2 | 2.746 | [16*]c1ccc(O)cc1 |
| 2463.6 | 31.9 | 34.9 | 78.3 | 175.7 | 975.1 | 3.168 | [5*]NC(═N)N |
| 2554.3 | 33.1 | 36.2 | 81.2 | 182.2 | 1011.2 | 3.306 | [1*]C(═O)[C@@H]([4*])CO |

Step 4 begins with the preparation of the drug target in PDBQT format. PDBQT is essential for molecular docking simulations, particularly when using software such as AutoDock. The PDB (Protein Data Bank) format contains the 3D structure of the drug target, which could be a protein or enzyme, while the QT (Quaternion) data provides information about the flexibility of the target, including potential conformational changes during docking. In this step, the drug target is processed by adding hydrogens, applying charges, and ensuring the structure is clean and ready for docking simulations.

Next, the SMILES notation for the drug candidates is validated to ensure the chemical structure is represented accurately. SMILES is a text-based representation of molecular structures, and this validation process checks for correctness and rectifies any issues, Table 6. After validation, the molecules are converted into 3D structures using molecular modeling software. This conversion is critical for docking, as molecular interactions depend on the 3D shape and conformation of the molecules, which need to be accurately represented for effective docking.

TABLE 6
SMILES Validation Results

| ChEMBL ID | Molecular Formula | smiles | Validation_Status |
|---|---|---|---|
| CHEMBL2103941 | C142H222N42O31 | [symbol] C[C@H]1C(═O)N[C@H](C(═O)N [symbol] | Valid |
| CHEMBL1229044 | C95H166N22O15 + 2 | [symbol] c2ccccc12)NC(═O)[C@@H](N) [symbol] | Valid |
| CHEMBL2425403 | C36H59N7O10S | [symbol] C)NC(═O)[C@H](C)NC(═O)[C@ [symbol] | Valid |
| CHEMBL2425396 | C38H56N14O11S | [symbol] CO)NC(═O)[C@H](Cc1ccc(O)c [symbol] | Valid |
| CHEMBL2103901 | C126H238N26O22 | [symbol] )[C@H](CC(C)C)NC(═O)[C@H]( [symbol] | Valid |
| CHEMBL2304033 | C22H36N8O11 | [symbol] (═O)[C@H](CC(═O)O)NC(═O)[ [symbol] | Valid |
| CHEMBL1191337 | C17H32N6O3 | [symbol] C@H](C═O)CCCN═C(N)N)C(═O [symbol] | Valid |
| CHEMBL3407793 | C40H63N9O15 | [symbol] O)NC(═O)[C@@H](NC(═O)[C@ [symbol] | Valid |
| CHEMBL3304875 | C69H86N14O14 | [symbol] c1c[nH]c2ccccc12)NC(═O)[C@ [symbol] | Valid |
| CHEMBL3667932 | C50H69N17O11 | [symbol] @H](Cc2c[nH]c3ccccc23)NC(═ [symbol] | Valid |
| CHEMBL1908986 | C57H73F3IN15O9 | [symbol] @@H](n)Cc1ccc(C2(C(F)(F)F) [symbol] | Valid |
| CHEMBL1207289 | C46H59N9O13S3 | [symbol] c1c[nH]c2ccccc12)C(═O)N[C@ [symbol] | Valid |
| CHEMBL3623789 | C53H87N21O17S2 | [symbol] C(═O)O)NC(═O)[C@H](CCCNC [symbol] | Valid |
| CHEMBL3946803 | C108H171N31O29 | [symbol] @@H](Cc1ccc(O)cc1)C(═O)N[ [symbol] | Valid |
| CHEMBL3985737 | C120H181N31O28 | [symbol] (═O)NCC(═O)N[C@@H](Cc1cc [symbol] | Valid |
| CHEMBL3984334 | C109H165N31O29S | [symbol] CC(═O)N[C@@H](Cc1ccc(O)c [symbol] | Valid |
| CHEMBL284201 | C27H48N6O7 | [symbol] ═O)N[C@@H](CC(C)C)C(═O)N1 [symbol] | Valid |
| CHEMBL3890815 | C118H177N31O27 | [symbol] C(═O)NCC(═O)N[C@@H](Cc1c [symbol] | Valid |
| CHEMBL3944455 | C118H187N33O27 | [symbol] ═O)NCC(═O)N[C@@H](Cc1ccc [symbol] | Valid |
| CHEMBL3890020 | C117H174N30O28 | [symbol] CC(═O)N[C@@H](Cc1ccc(O)cc [symbol] | Valid |
| CHEMBL3891294 | C112H171N31O29 | [symbol] C(═O)N[C@@H](Cc1ccc(O)cc1 [symbol] | Valid |
| CHEMBL3914919 | C142H226N40O31 | [symbol] [C@@H](Cc1ccccc1)C(═O)NC [symbol] | Valid |
| CHEMBL3948427 | C118H177N31O27 | [symbol] (═O)N[C@@H](Cc1ccc(O)cc1) [symbol] | Valid |
| CHEMBL1766929 | C38H64N12O8 | [symbol] CCCN1C(═O)[C@H](CCCNC(═N) [symbol] | Valid |

[symbol]

indicates data missing or illegible when filed

Once the drug targets and molecules are prepared, the next step is to dock the molecules to the drug target. Molecular docking simulates how well a molecule will bind to its target by positioning it in different orientations within the target's binding site. The docking algorithm then evaluates the binding affinity, predicting how strongly and favorably each molecule interacts with the target and determining the ideal binding pose. The docking assessment process takes into account several key factors, such as hydrophilic and hydrophobic interactions, hydrogen bonds (both donated and accepted), and the ligand orientation with the best complementarity score. Additionally, ionic interactions, aromatic interactions, Van der Waals forces, electrostatic forces, and free energies are all considered in the evaluation.

After completing the docking simulations, the results are ranked based on the binding affinity of each molecule to the drug target. Each molecule is assigned a score reflecting its ability to bind to the target, which takes into account factors like energy levels, molecular fit, and the nature of the interactions. The molecules are then ranked according to these scores, with higher-ranking molecules indicating stronger binding and better potential for effective interaction. This ranking system is crucial for prioritizing the most promising candidates for further optimization, helping researchers focus on molecules that are most likely to be successful in real-world applications.

Finally, lead molecules are identified. These are the top-ranked molecules that demonstrate the highest binding affinities to the target and exhibit favorable properties such as good pharmacokinetics, solubility, stability, and bioavailability. These lead molecules are selected for further optimization and experimental testing, marking the next stage in the drug discovery process.

In summary, Step 4 focuses on preparing the drug target in the appropriate format for docking simulations, validating and converting drug candidates' SMILES into 3D structures, performing molecular docking, and ranking the molecules based on their interaction with the target. The most promising candidates, identified as lead molecules, are selected for further optimization and experimental testing, advancing the drug discovery process.

The Neural Optimization Platform for Molecular Discovery has broad commercial applications across a wide range of industries due to its ability to accelerate the discovery and optimization of molecules with tailored properties. By integrating machine learning, computational chemistry, and traditional molecular modeling techniques, the platform offers significant advantages in terms of speed, accuracy, and cost-effectiveness. Below are the key commercial and space mission applications of the platform:

### Commercial Applications of the Neural Optimization Platform

The Neural Optimization Platform for Molecular Discovery is a versatile tool with applications across numerous industries, leveraging advanced machine learning, molecular modeling, and optimization techniques to design and refine molecules with tailored properties. Here are the key commercial applications:

### 1. Pharmaceutical and Drug Discovery

The platform significantly accelerates drug discovery by predicting interactions between molecules and biological targets like proteins, enzymes, and receptors. It designs molecules with enhanced bioactivity, selectivity, and reduced toxicity, streamlining the process and reducing experimental costs. Leveraging Graph Neural Networks (GNNs) and molecular docking simulations, it identifies promising compounds for conditions like Alzheimer's, Parkinson's, multiple sclerosis, and cancer. It also aids in enzyme inhibitor discovery and space-specific pharmaceutical development, advancing the treatment of complex diseases.

### 2. Material Science and Polymers

By predicting material properties such as mechanical strength, thermal stability, and biodegradability, the platform supports the development of high-performance materials. Applications include biodegradable polymers, advanced coatings, and sustainable materials for electronics, packaging, and other industries. This contributes to creating eco-friendly materials with reduced environmental impact.

### 3. Agricultural Chemicals and Pesticide Development

The platform enables the design of effective, environmentally friendly agricultural chemicals and pesticides. By predicting agrochemical properties like efficacy and environmental persistence, it aids in developing crop protection products that minimize chemical usage and ecological impact. This supports sustainable agricultural practices.

### 4. Environmental and Green Chemistry

In green chemistry, the platform designs molecules with reduced toxicity or biodegradability. It can create solutions for capturing carbon dioxide, cleaning up oil spills, or neutralizing hazardous waste. These applications address critical environmental challenges and promote sustainability.

### 5. Cosmetics and Personal Care Products

The platform helps design safe and effective molecules for skincare, haircare, and fragrance products. It optimizes formulations for moisturizing, anti-aging, and sun protection while creating biodegradable and non-toxic ingredients to meet consumer and regulatory demands for sustainable products.

### 6. Energy and Battery Technology

In the energy sector, the platform optimizes molecules for advanced batteries and energy storage solutions. By enhancing properties like conductivity and stability, it supports innovations in renewable energy storage, electric vehicles, and portable electronics, ensuring high performance and sustainability.

### 7. Food and Beverage Industry

The platform designs food additives, preservatives, and flavor compounds that enhance taste, texture, and nutritional value. It also predicts molecular interactions with food components and supports the development of eco-friendly packaging, addressing consumer preferences for sustainable products.

### 8. Biotechnology and Synthetic Biology

In biotechnology, the platform optimizes molecules for gene editing, enzyme engineering, and biosynthesis. Applications include industrial fermentation processes, diagnostic tests, and synthetic biological systems, enabling efficient production of biofuels, pharmaceuticals, and other bioproducts.

### 9. Chemical Manufacturing

The platform aids chemical manufacturing by optimizing reactions, predicting product yields, and designing sustainable processes. It reduces waste, energy consumption, and the use of hazardous materials, improving efficiency and environmental safety.

### 10. Custom Molecular Design for Niche Applications

With its flexibility, the platform supports the design of specialized molecules for specific projects, such as tailored drugs, materials for engineering applications, or unique industrial catalysts. It is particularly valuable for solving complex molecular challenges.

### 11. Defense and Security

The platform enhances defense applications by designing molecules for:
Explosives Detection: Sensors for high-sensitivity detection of explosives.
Personal Protection: Lightweight, impact-resistant materials for armor and helmets.
Chemical Warfare Protection: Molecules to neutralize or detoxify harmful agents.

### 12. Precision Agriculture

Applications in agriculture include:
Smart Fertilizers: Controlled-release molecules for optimized nutrient delivery.
Pesticide Alternatives: Biocompatible molecules that deter pests while protecting the environment.
Plant Growth Regulators: Molecules to enhance crop yields under varying conditions.

### 13. Artificial Intelligence Integration

The platform enhances AI applications through:
Explainable AI Models: Improved interpretability using molecular fingerprints and GNN data.
Automated Research Systems: Enabling autonomous laboratories for continuous molecular discovery.

### 14. Smart Textiles and Wearable Technology

The platform supports the development of:
Conductive Fibers: Smart textiles integrating sensors and energy storage.
Self-Healing Materials: Polymers capable of autonomous repair.
Functional Coatings: Molecules for moisture-wicking, UV-blocking, or antimicrobial textiles.

The Neural Optimization Platform serves as a transformative tool across industries, driving innovations that enhance efficiency, sustainability, and performance. Its applications demonstrate their potential to solve complex challenges and meet evolving market demands.

1: Generalized Method for Molecular Discovery
A computerized method for molecular discovery, comprising:
Receiving input molecular data containing molecular structures and corresponding properties;
Fragmenting the molecular structures into smaller, analyzable components based on predetermined fragmentation rules to preserve chemical and functional relevance;
Representing the fragmented molecular structures as computational data models suitable for machine learning, wherein the representation encodes atomic and bonding relationships;
Training a neural network on the computational data models to predict molecular descriptors, including chemical, physical, and biological properties;
Simulating interactions between the molecular components and biological or functional targets using computational modeling to assess potential interactions;
Refining molecular candidates by optimizing their predicted properties based on simulation outcomes;
Storing the refined molecular candidates and their associated predictions for further analysis or downstream applications.

2: Generalized System for Molecular Discovery
A computerized system for molecular discovery, comprising:
A molecular data module for storing and managing molecular structures and associated properties;
A fragmentation module for decomposing molecular structures into smaller fragments based on predefined fragmentation criteria;
A representation module for converting fragmented molecular structures into computational data models encoding atomic and bonding information;
A machine learning module for training a neural network to predict molecular descriptors based on the computational data models;
A simulation module for modeling interactions between molecular candidates and targets to evaluate potential performance or bioactivity;
An optimization module for refining the molecular candidates based on predicted properties and simulation results.

3: Neural Network Training for Molecular Descriptor Prediction
A computerized method for molecular descriptor prediction, comprising:
Representing molecular data, including molecular structures and associated properties, as computational models that encode chemical and structural features;
Training a neural network on the computational models to predict molecular descriptors, including at least one of chemical, physical, or biological properties;
Using the trained neural network to analyze new molecular data and predict descriptors for uncharacterized molecular structures;
Storing the predicted descriptors and associated molecular data for further use in molecular discovery and optimization.

4: The method of claim 1, wherein the fragmentation process is performed using the BRICS (Breaking of Rigid Chemical Substructures) method to decompose molecular structures into chemically stable and analyzable fragments.

5: The method of claim 1, wherein the computational data models are generated by representing the fragmented molecular structures as graphs, with nodes representing atoms and edges representing bonds.

6: The method of claim 1, wherein the neural network is configured as a Graph Neural Network (GNN) trained to process graph-based molecular representations and predict molecular descriptors.

7: The method of claim 1, wherein the GNN utilizes message-passing algorithms to aggregate atomic and bonding information across the molecular graph for enhanced prediction accuracy.

8: The method of claim 1, further comprising storing the fragmented molecular data and predicted molecular descriptors in a structured file format, such as a database or Excel file.

9: The system of claim 2, wherein the fragmentation module applies the BRICS method to generate fragments that retain functional groups critical for bioactivity.

10: The system of claim 2, wherein the representation module generates graph-based molecular representations suitable for training machine learning models.

11: The system of claim 2, wherein the machine learning module includes a Graph Neural Network (GNN) configured to predict molecular descriptors, such as solubility, reactivity, bioactivity, and toxicity.

12: The system of claim 2, wherein the optimization module incorporates multi-objective optimization techniques to refine molecular properties.
